(19) United States
(12) Patent Application Publication
(10) Pub. No.: US 2024/0222440 A1
(43) Pub. Date: Jul. 4, 2024

(54) TRANSISTOR WITH A BODY AND BACK GATE STRUCTURE IN DIFFERENT MATERIAL LAYERS

(71) Applicant: Intel Corporation, Santa Clara, CA (US)

(72) Inventors: Samuel James BADER, Hillsboro, OR (US); Han Wui THEN, Portland, OR (US); Ibrahim BAN, Beaverton, OR (US); Heli Chetanbhai VORA, Hillsboro, OR (US); Marko RADOSAVLJEVIC, Portland, OR (US)

(21) Appl. No.: 18/089,919

(22) Filed: Dec. 28, 2022

(51) Int. Cl. H01L 29/267; H01L 21/02; H01L 21/18; H01L 21/3205; H01L 29/06; H01L 29/10; H01L 29/423; H01L 29/66; H01L 29/778; H01L 29/78

(52) U.S. Cl. CPC H01L 29/267; H01L 21/0254; H01L 21/185; H01L 21/32051; H01L 29/0607; H01L 29/1033; H01L 29/42356; H01L 29/42392; H01L 29/66522; H01L 29/7786; H01L 29/78

(57) ABSTRACT

Embodiments described herein may be related to apparatuses, processes, systems, and/or techniques for using layer transfer techniques to bond a silicon layer with a GaN layer, where the silicon layer includes a first portion of a device, for example a transistor, and the GaN layer includes a second portion of the device. Other embodiments may be described and/or claimed.

### FIELD

Embodiments of the present disclosure generally relate to the field of semiconductor manufacturing, and in particular to testing for defects on a wafer.

### BACKGROUND

Continued growth in virtual machines, cloud computing, and portable devices will continue to increase the demand for high density transistors within chips and semiconductor packages.

### BRIEF DESCRIPTION OF THE DRAWINGS

FIGS. 1A-1G show cross section side views of stages in a manufacturing process for bonding a silicon crystal layer to a gallium nitride (GaN) wafer using layer transfer integration techniques, where the silicon layer includes a portion of a transistor device, in accordance with various embodiments.

FIGS. 2A-2G show cross section side views of stages in a manufacturing process for bonding a silicon crystal layer to a GaN wafer using layer transfer integration techniques, where the GaN wafer includes a metallization layer, in accordance with various embodiments.

FIGS. 3A-3B show a cross-section side view and a top-down view of a silicon layer that has been bonded to a GaN layer using layer transfer techniques, where the silicon layer includes a transistor and the GaN layer includes a conductive layer that serves as a back gate control to the transistor, in accordance with various embodiments.

FIGS. 4A-4B show cross section side views of a silicon layer that has been bonded to a GaN layer using layer transfer techniques, where the silicon layer includes a transistor and the GaN layer includes a contact metal layer that serves as a back gate control to the transistor, in accordance with various embodiments.

FIG. 5 shows a cross-section side view of a silicon layer that has been bonded to a GaN layer using layer transfer techniques, where the silicon layer includes a transistor that is directly electrically coupled with a contact metal layer in the GaN layer that serves as a back gate structure for the transistor, in accordance with various embodiments.

FIG. 6 shows a cross-section side view of a silicon layer that has been bonded to a GaN layer using layer transfer techniques, where the silicon layer includes a transistor and the GaN layer includes a conductive layer that is electrically coupled with the source of the transistor, where the conductive layer serves as a source-connected field plate for the transistor, in accordance with various embodiments.

FIG. 7 shows a cross-section side view of a silicon layer that has been bonded to a GaN layer using layer transfer techniques, where the GaN layer includes a transistor and the silicon layer includes a conductive layer that is electrically coupled with the source of the transistor in the GaN layer, where the conductive layer serves as a source-connected field plate for the transistor, in accordance with various embodiments.

FIG. 8 shows a cross section side view of a silicon layer that has been bonded with a GaN layer using layer transfer techniques, where the silicon layer includes a transistor and the GaN layer includes a conductive layer that serves as a back gate structure for the transistor, where the transistor contacts penetrate the bonding oxide, in accordance with various embodiments.

FIG. 9 illustrates an example process for manufacturing a voltage contrast structure, in accordance with various embodiments.

FIG. 10 illustrates a computing device in accordance with one implementation of the invention.

FIG. 11 illustrates an interposer that includes one or more embodiments of the invention.

### DETAILED DESCRIPTION

Embodiments described herein may be related to apparatuses, processes, systems, and/or techniques for using layer transfer processes, which may also be referred to as layer transfer integration, 3D layer transfer process, or layer transfer bonding, to bond a silicon layer with a GaN layer, where the silicon layer includes a first portion of a device and the GaN layer includes a second portion of the device. In embodiments, the device may be part of a semiconductor package.

For example, the device may be a transistor, and the silicon layer may include the body of the transistor and the GaN layer may include a field plate or a back gate structure for the transistor. In a similar example, the silicon layer may include a field plate or a back gate structure for a transistor that is in the GaN layer. In embodiments, the GaN layer may include an aluminum gallium nitride (AlGaN) layer that is on a GaN layer. In embodiments, there may be an aluminum nitride (AlN) layer between the AlGaN layer and the GaN layer.

In embodiments, the layer referred to herein as the silicon layer may actually be any material, and the GaN layer may be any material. For example, the layer referred to herein as the GaN layer may actually be a silicon carbide (SiC) layer, or may be some other material, for example from semiconductor families and that may be combined, such as SiC, SiGe, a group III-V material, GaN, silicon, and the like. In embodiments, the GaN layer may be used to form higher power devices and devices within the silicon layer may be used to control the higher power devices. In embodiments, layer transfer techniques may be used to tightly integrate devices or portions of devices in the GaN layer with devices or portions of devices in the silicon layer.

Multiple transistors or electrical devices belonging to different classes or material platforms may be integrated using layer transfer techniques, in order to make use of the individual strengths of these devices within different materials. For example, using different materials that have different bandgaps. By using layer transfer techniques, these devices can be tightly integrated into a same substrate, eliminating chip-to-chip parasitics.

In some implementations, silicon CMOS transistors may be integrated with GaN power transistors where some processing, or complete processing, of devices on one material platform, in addition to potentially some limited interconnectivity, is then followed by integration of another material platform. A continuation of processing may then occur to create second devices that may then potentially complete the processing of the first devices, with subsequent stages interconnecting all devices. In these embodiments, this sort of process flow is used not only to integrate dissimilar devices for reduced parasitics, but also to enhance the individual devices by using the layers of one device's process to support the other device.

In embodiments described herein, a layer in one material, for example GaN, which may be used for a power device, may inherently provide an additional benefit to the other device in a silicon layer. For example, a silicon transistor in a silicon layer may use a conductive layer, which may be referred to as a conductive semiconductor region, which may include a 2D electron gas (2DEG), which may be referred to as a 2DEG channel, or a metallized layer within a GaN layer to form a complete transistor. In embodiments, the 2DEG may be induced by a junction of AlGaN and GaN material. In embodiments the conductive semiconductor region may be a doped region of SiC, group III-V material, Si, GaN, or AlGaN.

In this way, the conductive layer or metallized layer in the GaN layer may be used to gate or field-shape the transistor by being placed directly above or below the other portion of the device in a layer transfer scheme. Similarly, a structure in a silicon layer may be electrically coupled with a source of a transistor in a metallized layer within the GaN layer, where the structure in the silicon layer may serve as a source field plate for the transistor within the GaN layer.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an ASIC, an electronic circuit, a processor (shared, dedicated, or group) and/or memory (shared, dedicated, or group) that execute one or more software or firmware programs, a combinational logic circuit, and/or other suitable components that provide the described functionality.

Various Figures herein may depict one or more layers of one or more package assemblies. The layers depicted herein are depicted as examples of relative positions of the layers of the different package assemblies. The layers are depicted for the purposes of explanation, and are not drawn to scale. Therefore, comparative sizes of layers should not be assumed from the Figures, and sizes, thicknesses, or dimensions may be assumed for some embodiments only where specifically indicated or discussed.

Various embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

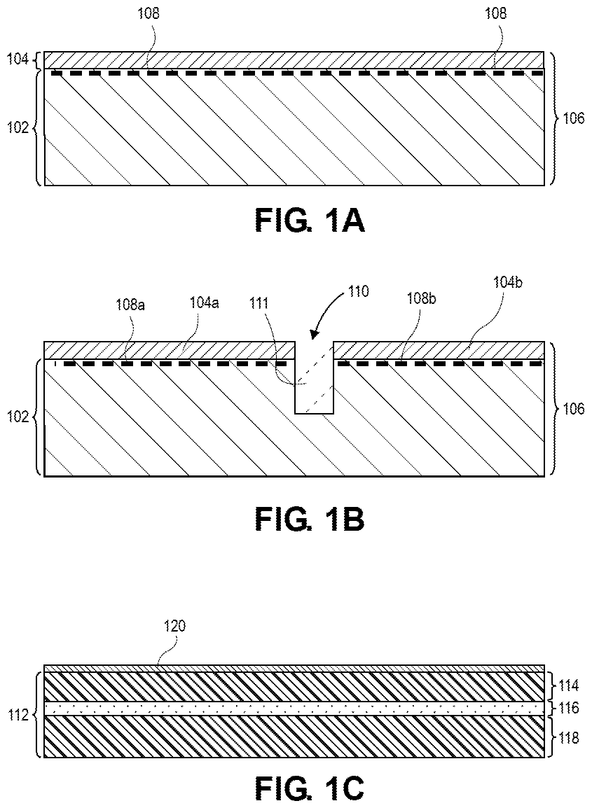

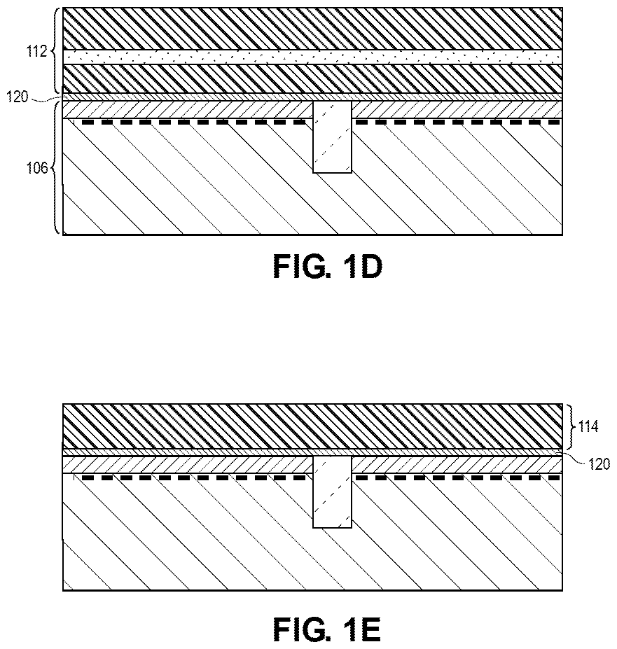

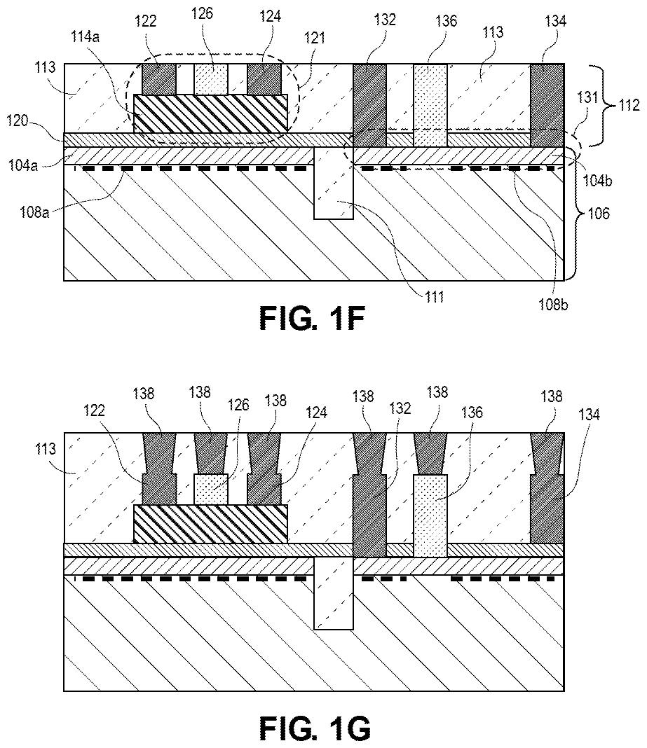

FIGS. 1A-1G show cross section side views of stages in a manufacturing process for bonding a silicon crystal layer to a GaN wafer using layer transfer integration techniques, where the silicon layer includes a portion of a transistor device, in accordance with various embodiments. FIG. 1A shows a cross-section side view of a GaN layer 102, with an AlGaN layer 104 on top of the GaN layer 102. In some embodiments, an aluminum nitride (AlN) interlayer (not shown) may be between the GaN layer 102 and the AlGaN layer 104. And in some embodiments, an additional GaN or AlGaN layer (not shown), which may be potentially doped, may sit atop and/or replace part of AlGaN layer 104. These layers may be referred to as p-GaN gate devices or as epistructures with GaN caps. The GaN layer 102 and the AlGaN layer 104 together may make up a first layer 106. In embodiments, the GaN layer 102 may be all or a portion of a GaN wafer. In embodiments, a thickness of the AlGaN layer 104 may range from 1 to 50 nm.

In embodiments, a 2D electron gas (2DEG) 108 may form near the interface between the GaN layer 102 and the AlGaN layer 104. In embodiments, the 2DEG may serve as a conductive layer that may be used as portions of a device that may be fabricated in the silicon layer as discussed further below. It should be appreciated that in other embodiments the GaN layer 102 and AlGaN layer may be some other material, such as SiC, SiGe, a group III-V material. In embodiments, the GaN layer 102 may be on a silicon substrate (not shown). Note that in some embodiments, the AlGaN layer 104 may not be present.

FIG. 1B shows a cross-section side view, that may be similar to FIG. 1A, where a trench 110 may be formed that extends through the AlGaN layer 104 of FIG. 1A, and creates a first AlGaN layer 104a and a second AlGaN layer 104b. The trench 110 may extend at least partially into the GaN layer 102. As a result, the 2DEG 108 of FIG. 1A may be split into 2 2DEG layers 108a, 108b. Note that the trench 110 may partially or completely surround the first AlGaN layer 104a to create a mesa structure. In embodiments, the trench 110 may be formed using an etching processes that may be known in the art. A dielectric 111 may be placed within the trench 110.

FIG. 1C shows a cross-section side view of a second layer 112 that includes a silicon layer 114, which may include silicon crystal. In embodiments, there may be a carrier wafer 118, which may also include silicon, that is separated from the silicon layer 114 by an etch stop layer 116. In embodiments, a bonding oxide layer 120 may be on a side of the silicon layer 114.

FIG. 1D shows a cross-section side view where the first layer 106 of FIG. 1B may be layer transferred and bonded to the second layer 112 using the bonding oxide layer 120. In embodiments, the layer transferring techniques may be referred to as 3D layer transferring processes.

FIG. 1E shows a cross-section side view where the carrier wafer 118, which may also be referred to as a donor wafer, and the etch stop layer 116 of FIG. 1C may be removed, leaving the silicon layer 114 on top of the bonding oxide layer 120. Note that in embodiments, the silicon layer 114 may be further thinned in preparation for following stages.

FIG. 1F shows a cross-section side view where a silicon portion 114a of the silicon layer 114 of FIG. 1E may be used to create a body of a transistor. In embodiments, a source contact 122, a drain contact 124, and a gate 126 may be placed on the silicon portion 114a to create partial transistor 121. Note that the partial transistor 121 is just above the bonding oxide layer 120, which is just above the first AlGaN layer 104a and the first 2DEG layer 108a.

In embodiments, a source contact 132, a drain contact 134, and a gate 136 may be formed through the second layer 112 and through the bonding oxide layer 120 and come into direct physical contact with the second AlGaN layer 104b, just above the second 2DEG layer 108b. In some embodiments, more complicated contact schemes, for example epitaxial regrowth at some stage in the process, may also be used. Similarly, the gate stack may be more complicated than as shown, incorporating, for example, etches into the AlGaN and/or GaN layers, uses of additional gate dielectrics, use of p-type GaN or AlGaN, and the like. As a result, a transistor 131 within the first layer 106 may be formed. A dielectric 113, which may be similar to dielectric 111, may be placed above the bonding oxide layer 120.

FIG. 1G shows a cross-section side view where continued backend processing may occur, where vias 138 may be formed through the dielectric 113 to electrically couple, respectively, with the source contact 122, drain contact 124, gate 126, source contact 132, drain contact 134, and gate 136.

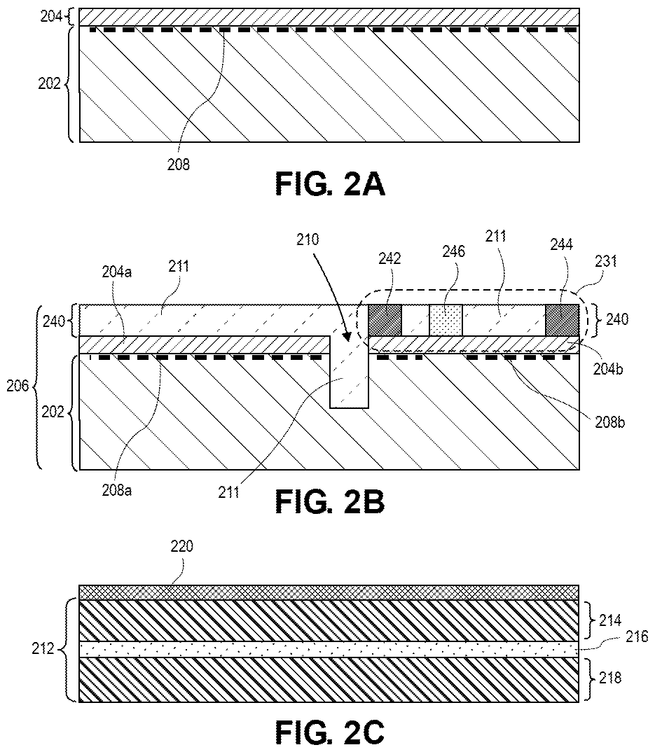

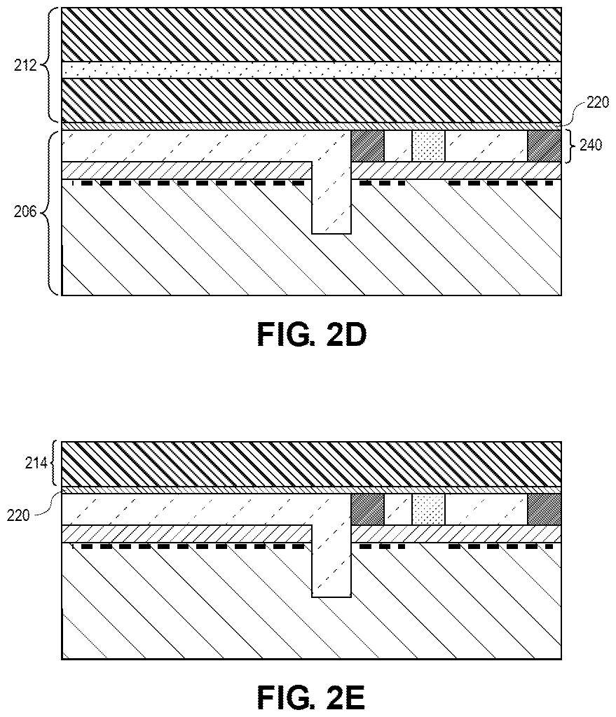

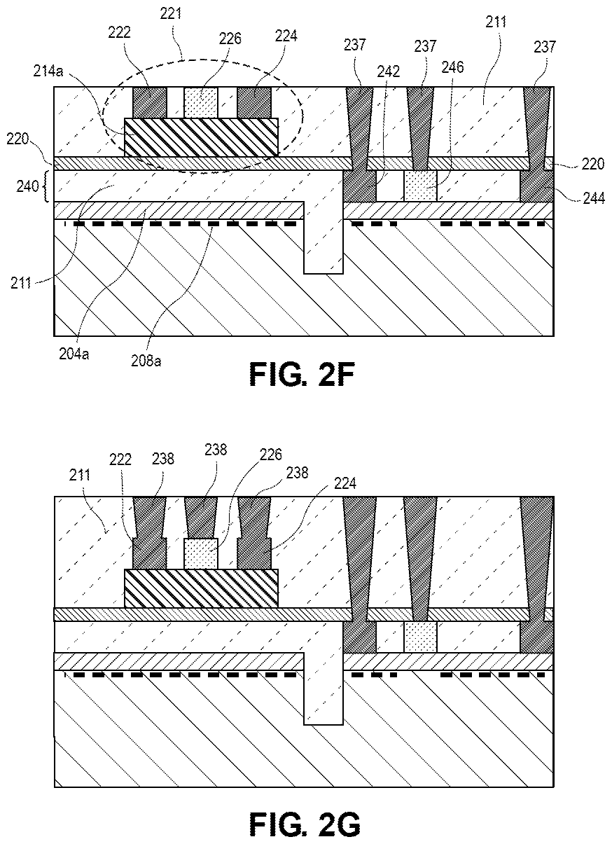

FIGS. 2A-2G show cross section side views of stages in a manufacturing process for bonding a silicon crystal layer to a GaN wafer using layer transfer integration techniques, where the GaN wafer includes a metallization layer, in accordance with various embodiments. FIG. 2A, which may be similar to FIG. 1A, shows a cross-section side view of a GaN layer 202, with an AlGaN layer 204, which may be similar to AlGaN layer 104 of FIG. 1A, on top of the GaN layer 202. In some embodiments, an AlN interlayer (not shown) may be between the GaN layer 202 and the AlGaN layer 204. In embodiments, the GaN layer 202 may be all or a portion of a GaN wafer. In embodiments, a 2DEG layer 208, which may be similar to 2DEG layer 108 of FIG. 1A, may form near the interface between the GaN layer 202 and the AlGaN layer 204.

FIG. 2B shows a cross-section side view where a trench 210 may be formed that extends through the AlGaN layer 204 of FIG. 1A, and creates a first AlGaN layer 204a and a second AlGaN layer 204b. The trench 210 may extend at least partially into the GaN layer 202. As a result, the 2DEG 208 of FIG. 1A may be split into 2 2DEG layers 208a, 208b. Note that the trench 210 may partially or completely surround the first AlGaN layer 204a to create a mesa structure. In embodiments, the trench 210 may be formed using an etching processes that may be known in the art. In embodiments, a dielectric 211 may be placed within the trench 210.

In embodiments, a metallization layer 240 may be above the first AlGaN layer 204a or the second AlGaN layer 204b (as shown). In embodiments, the metallization layer 240 may include a source contact 242, a drain contact 244, and a gate 246 that are above and may be in direct physical contact with the second AlGaN layer 204b. As a result, a first layer 206 may be formed, with the transistor 231 formed in the first layer 206. Note that in embodiments, the dielectric 211 may extend above the first AlGaN layer 204a and the second AlGaN layer 204b.

FIG. 2C, which may be similar to FIG. 1C, shows a cross-section side view of a second layer 212 that includes a silicon layer 214, which may include silicon crystal. In embodiments, there may be a carrier wafer 218, which may be referred to as a donor wafer and which may also include silicon, that is separated from the silicon layer 214 by an etch stop layer 216. In embodiments, a bonding oxide layer 220, which may be similar to bonding oxide layer 120 of FIG. 1C, may be on a side of the silicon layer 214.

FIG. 2D shows a cross-section side view where the second layer 212 of FIG. 2B may be layer transferred and bonded to the first layer 206 using the bonding oxide layer 220. In embodiments, the layer transferring techniques may be referred to as a 3D layer transferring process. As a result, the first layer 206 and the second layer 212 are monolithically integrated. Note that the metallization layer 240 of the first layer 206 is below the bonding oxide layer 220.

FIG. 2E shows a cross-section side view where the carrier wafer 218 and the etch stop layer 216 of FIG. 2C may be removed, leaving the silicon layer 214 on top of the bonding oxide layer 220. Note that in embodiments, the silicon layer 214 may be further thinned in preparation for following stages.

FIG. 2F shows a cross-section side view where a silicon portion 214a of the silicon layer 214 of FIG. 2E is used to create a body of a transistor. In embodiments, a source contact 222, a drain contact 224, and a gate 226 may be placed on the silicon portion 214a to create partial transistor 221. Note that the partial transistor 221 is just above the bonding oxide layer 220, with a dielectric 211 between the bonding oxide layer 220 within the metallization layer 240, which is above the first AlGaN layer 204a and the first 2DEG layer 208a.

In embodiments, during continued backend processing vias 237 may be created that extend through the dielectric 211 and the bonding oxide layer 220 and come into direct physical and electrical contact with the source contact 242, the drain contact 244, and the gate 246 respectively.

FIG. 2G shows a cross-section side view where continued backend processing may occur, where vias 238 may be formed through the dielectric 211 to electrically couple, respectively, with the source contact 222, the drain contact 224, and the gate 226.

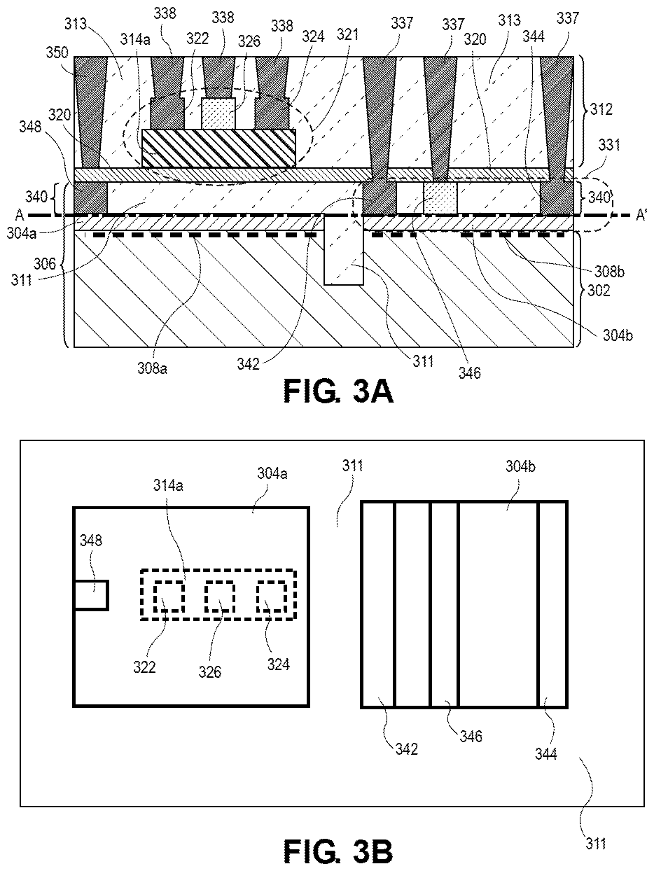

FIGS. 3A-3B show a cross-section side view and a top-down view of a silicon layer that has been bonded to a GaN layer using layer transfer techniques, where the silicon layer includes a transistor and the GaN layer includes a conductive layer that serves as a back gate control to the transistor, in accordance with various embodiments. FIG. 3A, which may be similar to FIG. 2F, shows a cross-section side view of a first layer 306, which may include a GaN layer 302, with a first AlGaN layer 304a and a second AlGaN layer 304b on top of the GaN layer 302, where the first AlGaN layer 304a and the second AlGaN layer 304b are electrically isolated from each other by a dielectric 311. A first 2DEG layer 308a may be below the first AlGaN layer 304a, and a second 2DEG layer 308b may be below the second AlGaN layer 304b.

In embodiments, a metallization layer 340, may be part of the first layer 306 and above the AlGaN layers 304a, 304b. In embodiments, a contact 348 may be within the metallization layer 340 and may be directly electrically coupled with the first AlGaN layer 304a. In embodiments, a source contact 342, a drain contact 344, and a gate 346 may be within the metallization layer 340 and may be directly electrically coupled with the second AlGaN layer 304b, to form a GaN transistor 331.

The second layer 312 may include a silicon portion 314a of the silicon layer 214 of FIG. 2E that is used to create a body of a transistor. In embodiments, a source contact 322, a drain contact 324, and a gate 326 may be placed on the silicon portion 314a to create partial silicon transistor 321. In embodiments, the partial silicon transistor 321 may be any semiconductor structure. In embodiments, vias 338 may be formed that directly electrically contact, respectively, the source contact 322, the drain contact 324, and the gate 326. In embodiments, vias 337 may be formed that directly electrically contact, respectively, the source contact 342, the drain contact 344, and the gate 346. Note that the partial silicon transistor 321 is just above the bonding oxide layer 320, which is above the first AlGaN layer 304a and the first 2DEG layer 308a. In embodiments, the partial silicon transistor 321 may be proximate to the first AlGaN layer 304a and the first 2DEG layer 308a, where the partial silicon transistor 321 may be at a distance from the first AlGaN layer 304a and/or the first 2DEG layer 308a, perpendicular to the first AlGaN layer 304a or to the bonding oxide layer 320, that is less than 1 micrometers, and often in the range of tens of nanometers (nm). In embodiments, the distance may be less than 100 nm. In embodiments, there may be a dielectric 311 between the bonding oxide layer 320 and the first AlGaN layer 304a.

In embodiments, a via 350 may extend through dielectric 313 of the second layer 312, through the bonding oxide layer 320, and directly electrically couple with contact 348. Because the contact 348 is electrically coupled with the first AlGaN layer 304a and proximate to the first 2DEG layer 308a, voltage applied to the via 350 will propagate through the first 2DEG layer 308a acting like a metal, and thus provide a back gate control, by providing an electric field to the partial silicon transistor 321. In embodiments, this back gate function may be used to tune the threshold voltage of the partial silicon transistor 321 by altering the voltage applied to the via 350 to alter the electric field.

In embodiments, when these techniques are applied to multiple transistors, performance may be improved, or power consumption reduced on a transistor-by-transistor basis, based upon how each transistor is used. For example, if the back gate function performed by the first 2DEG layer 308a is used to turn off the partial silicon transistor 321 more, this may cause the partial silicon transistor 321 to be used in a lower power mode. If the back gate function performed by the first 2DEG layer 308a is used to turn on the partial silicon transistor 321 more, this may cause the partial silicon transistor 321 to be used as a higher-performance transistor, and this may be adjusted dynamically. In this way, the partial silicon transistor 321 in the second layer 312, which may be a silicon layer, uses the first 2DEG layer 308a in the first layer 306 as a back gate.

In other embodiments, a plurality of partial silicon transistors 321 (not shown) that are above the 2DEG layer 308a may use the 2DEG layer 308a to make global performance adjustments to the plurality of silicon transistors based upon a state of the overall system, for example when entering sleep mode or adjusting power overhead for a low/high utilization. In embodiments, these techniques may be used to improve the energy efficiency of the overall system.

FIG. 3B shows a top-down cross-section view at A-A′ of FIG. 3A. The first AlGaN layer 304a shows as a mesa, and the second AlGaN layer 304b shows as another mesa that are separated by a dielectric 311. The contact 348 is on the first AlGaN layer 304a, with the silicon portion 314a above the first AlGaN layer 304a that includes a source contact 322, drain contact 324, and gate 326 on the silicon portion 314a. The metallization layer 340 above the second AlGaN layer 304b includes the source contact 342, the drain contact 344, and the gate 346.

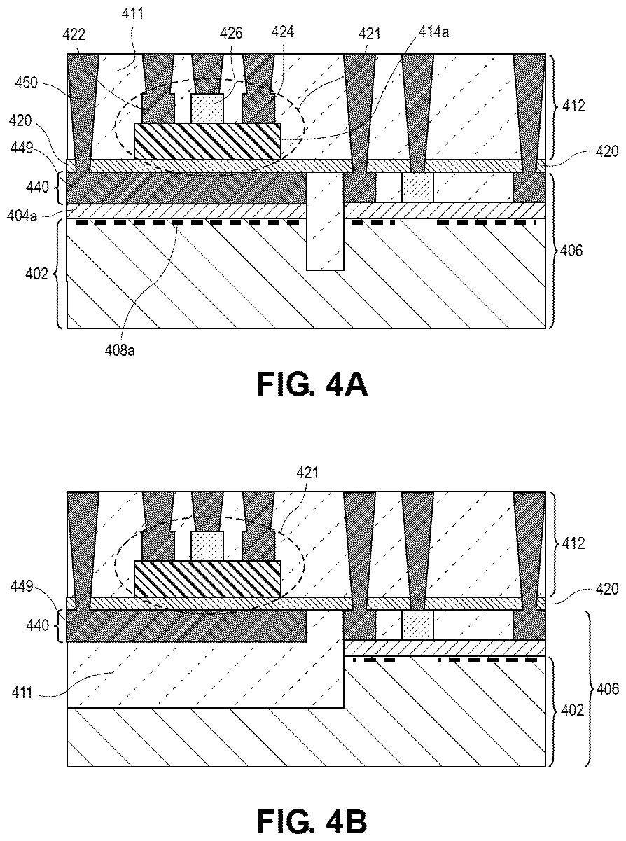

FIGS. 4A-4B show cross section side views of a silicon layer that has been bonded to a GaN layer using layer transfer techniques, where the silicon layer includes a transistor and the GaN layer includes a contact metal layer that serves as a back gate control to the transistor, in accordance with various embodiments. FIGS. 4A-4B may be similar to FIG. 3A. FIG. 4A shows a cross-section side view that includes a first layer 406 with a GaN layer 402 and a AlGaN layer 404a on top of the GaN layer 402, and metallization layer 440 that includes a contact metal layer 449 on top of the first AlGaN layer 404a. A bonding oxide layer 420 is above the metallization layer 440. In embodiments, a silicon transistor 421 may be in a second layer 412 that includes silicon, and is above the bonding oxide layer 420 and above the contact metal layer 449. The silicon transistor 421 may include a portion of silicon 414a that serves as a transistor body, with a source contact 422, a drain contact 424, and a gate 426 on the portion of silicon 414a. In embodiments, the silicon transistor 421 may be proximate to the contact metal layer 449, where the silicon transistor 421 may be at a distance from the contact metal layer 449, perpendicular to the contact metal layer 449 or to the bonding oxide layer 420, that is less than 1 micrometers and often in the range of tens of nanometers. In embodiments, the distance may be less than 100 nm. In embodiments the silicon transistor 421 may be any semiconductor structure.

In embodiments, a metal via 450, which may be referred to as an electrical connection, may extend through the dielectric 411 and through the bonding oxide layer 420 and directly electrically couple with the contact metal layer 449. In this implementation, the contact metal layer 449 may serve as a back gate for the silicon transistor 421. In embodiments, depending upon the presence of the contact metal layer 449 beneath the silicon transistor 421, the 2DEG layer 408a may play a reduced role, or no role at all, in providing a back gate function.

FIG. 4B shows another embodiment, similar to FIG. 4A, where the metallization layer 440 within the first layer 406 includes the contact metal layer 449 that is beneath the silicon transistor 421, which is in the second layer 412, to provide a back gate function for the silicon transistor 421. However, in this embodiment, there is no AlGaN layer similar to AlGaN layer 404a of FIG. 4A to serve the back gate function. Instead, there is a dielectric 411 within the GaN layer 402 of first layer 406. In other embodiments (not shown) some other material other than the dielectric 411 may be used, including materials that do not form a 2DEG such as 2DEG 408a of FIG. 4A.

Note that in the embodiments shown with respect to FIGS. 4A-4B, the back gate function provided by contact metal layer 449 is in a configuration that brings it very close to the silicon transistor 421, for example separated only by the bonding oxide layer 420. These configurations provide a greater degree of control of the back gate function over the silicon transistor 421 by increasing the electric field effect that the contact metal layer 449 has over the silicon transistor 421.

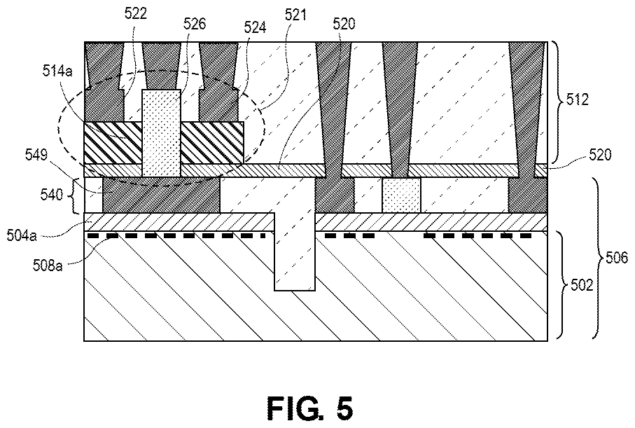

FIG. 5 shows a cross-section side view of a silicon layer that has been bonded to a GaN layer using layer transfer techniques, where the silicon layer includes a transistor that is directly electrically coupled with a contact metal layer in the GaN layer that serves as a back gate structure for the transistor, in accordance with various embodiments. FIG. 5, which may be similar to FIG. 4A, shows a cross-section side view that includes a first layer 506 with a GaN layer 502 and a AlGaN layer 504a on top of the GaN layer 502, and metallization layer 540 that includes a contact metal layer 549 on top of the first AlGaN layer 504a. A bonding oxide layer 520 is above the metallization layer 540. A second layer 512 that may include silicon may be above the bonding oxide layer 520. In embodiments, a silicon transistor 521 may be above the bonding oxide layer 520 and above the contact metal layer 549. The silicon transistor 521 may include a portion of silicon 514a that serves as a transistor body, with a source contact 522, a drain contact 524, and a gate 526 on the portion of silicon 514a. In embodiments, the silicon transistor 521 may be any semiconductor structure.

In embodiments, the gate 526 may extend around the portion of silicon 514a and through the bonding oxide layer 520 and directly electrically couple with the contact metal layer 549, forming a gate-all-around (GAA) style device. In this implementation, the contact metal layer 549 may serve as a back gate for the silicon transistor 521.

In embodiments, depending upon the area of the contact metal layer 549 beneath the silicon transistor 521, the 2DEG layer 508a may play a reduced role, or no role at all, in providing a back gate function, thus the AlGaN layer 504a and those under it may be removed without affecting the device. This embodiment, while similar to the embodiment shown with respect to FIG. 4A, eliminates the need for the metal via 450 of FIG. 4A, and as a result the contact metal layer 549 may be more compact and reduce the overall area required for the proper operation of the silicon transistor 521.

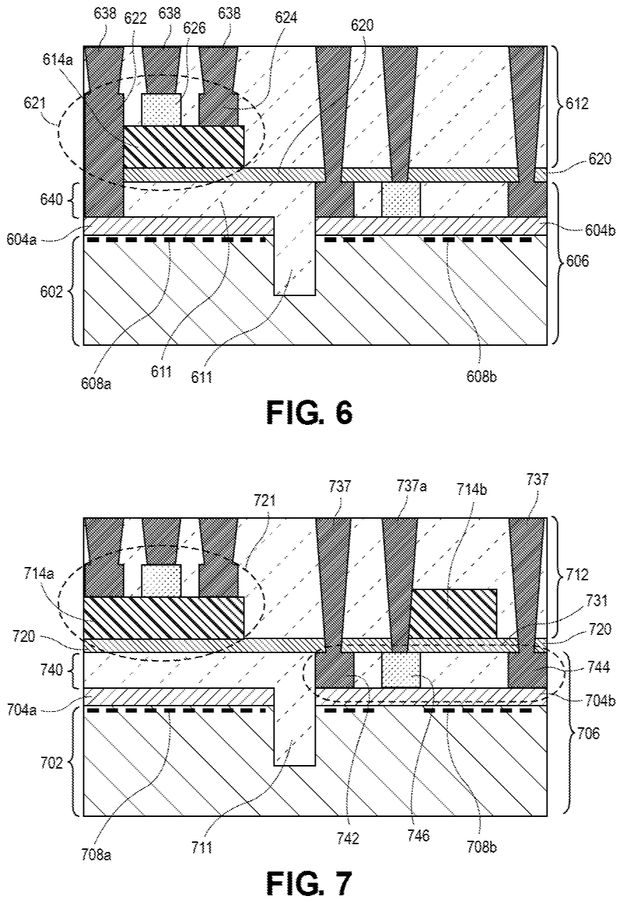

FIG. 6 shows a cross-section side view of a silicon layer that has been bonded to a GaN layer using layer transfer techniques, where the silicon layer includes a transistor and the GaN layer includes a conductive layer that is electrically coupled with the source of the transistor, where the conductive layer serves as a source-connected field plate for the transistor, in accordance with various embodiments. FIG. 6 may be similar to FIG. 3A as described above. FIG. 6 shows a cross-section side view of a first layer 606, which may include a GaN layer 602, with a first AlGaN layer 604a and a second AlGaN layer 604b on top of the GaN layer 602, where the first AlGaN layer 604a and the second AlGaN layer 604b are isolated from each other by a dielectric 611. A first 2DEG layer 608a may be below the first AlGaN layer 604a, and a second 2DEG layer 608b may be below the second AlGaN layer 604b. In embodiments, a metallization layer 640, may be part of the first layer 606 and above the AlGaN layers 604a, 604b.

The second layer 612 may include a silicon portion 614a of the silicon layer 214 of FIG. 2E that is used to create a body of a transistor. In embodiments, a drain contact 624 and a gate 626 may be placed on the silicon portion 614a to create silicon transistor 621. In embodiments, the silicon transistor 621 may be any semiconductor structure. In embodiments, a source contact 622 may be formed, for example using an etching process, that is electrically coupled with the silicon portion 614a, and extends through the second layer 612, through the bonding oxide layer 620, and into the first layer 606 and forms a direct electrical contact with the first AlGaN layer 604a. In embodiments, the source contact 622 may be referred to as electrical connection. As a result, the first 2DEG layer 608a beneath the silicon transistor 621 may serve as a source-connected field plate for the silicon transistor 621. In embodiments, the source-connected field plate may help improve the breakdown properties of the silicon transistor 621. In embodiments, the silicon transistor 621 may be proximate to the first AlGaN layer 604a and the first 2DEG layer 608a, where the silicon transistor 621 may be at a distance from the first AlGaN layer 604a and/or the first 2DEG layer 608a, perpendicular to the first AlGaN layer 604a, that is less than 1 micrometers. As in previous embodiments, a metallization layer belonging above the AlGaN 604a below bonding oxide 620 may be used instead of the 2DEG to provide backgating closer to the transistor.

In embodiments, vias 638 may be formed that directly electrically contact, respectively, the source contact 622, the drain contact 624, and the gate 626. Note that the transistor 621 is just above the bonding oxide layer 620, which is above the first AlGaN layer 604a and the first 2DEG layer 608a. In embodiments, there may be a dielectric 611 between the bonding oxide layer 620 and the first AlGaN layer 604a.

FIG. 7 shows a cross-section side view of a silicon layer that has been bonded to a GaN layer using layer transfer techniques, where the GaN layer includes a transistor and the silicon layer includes a conductive layer that is electrically coupled with the source of the transistor in the GaN layer, where the conductive layer serves as a source-connected field plate for the transistor, in accordance with various embodiments. FIG. 7 may be similar to FIG. 6. FIG. 7 shows a cross-section side view of a first layer 706, which may include a GaN layer 702, with a first AlGaN layer 704a and a second AlGaN layer 704b on top of the GaN layer 702, where the first AlGaN layer 704a and the second AlGaN layer 704b are isolated from each other by a dielectric 711. A first 2DEG layer 708a may be below the first AlGaN layer 704a, and a second 2DEG layer 708b may be below the second AlGaN layer 704b.

In embodiments, a metallization layer 740, may be part of the first layer 706 and above the AlGaN layers 704a, 704b. A source contact 742, a gate 746, and a drain contact 744 may be within the metallization layer 740, and may be on the second AlGaN layer 704b and above the second 2DEG layer 708b. In embodiments, the source contact 742, the gate 746 and the drain contact 744, along with a portion of the second AlGaN layer 704b and/or the GaN layer 702 may form a GaN transistor 731.

In embodiments, metal vias 737 may extend through the second layer 712, through the bonding oxide layer 720, and directly electrically and physically couple with the source contact 742 and the drain contact 744, respectively. Metal via 737a may extend through the second layer 712, through the bonding oxide layer 720, and directly electrically physically couple with the gate 746.

In embodiments, the second layer 712 may include a silicon transistor 721, which may be similar to partial silicon transistor 321 of FIG. 3A, which includes a silicon body 714a, which may have been formed, for example, from silicon layer 214 of FIG. 2E. The silicon transistor 721 may be above the first 2DEG layer 708a. The second layer 712 may include another portion of silicon 714b, which may have been formed, for example, from silicon layer 214 of FIG. 2E. In embodiments, the portion of silicon 714b may act as a gate-connected field plate in the second layer 712 for the GaN transistor 731 in the first layer 706. In embodiments, the silicon transistor 721 may be any semiconductor structure.

In these embodiments, there may be a high-voltage that is applied to the drain contact 744 which may result in a large electric field between the drain contact 744 and the gate 746. Without the gate-connected field plate function of the portion of silicon 714b, these electric fields may be highly non-uniform. For example, there may be an electric field spike near the edge of the gate 746. As a result, this may make the GaN transistor 731 more likely to break down at the location of the electric field spike. In embodiments, the gate-connected field plate provides an additional electrically conductive layer to supply some charge in order to rearrange the electric field and to flatten the electric field, thereby increasing the voltage which can be sustained.

Although in this embodiment, the portion of silicon 714b acts as a gate-connected field plate, in other embodiments the portion of silicon 714b may be electrically coupled with the source contact 742, in which the portion of silicon 714b will serve as a source-connected field plate. This can have additional advantages, for example, reducing gate-to-drain capacitance.

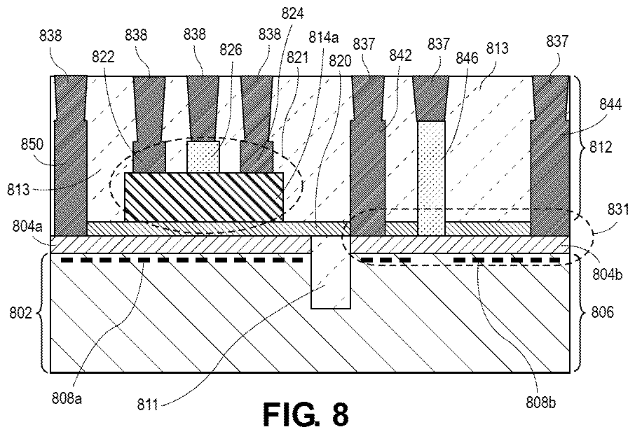

FIG. 8 shows a cross section side view of a silicon layer that has been bonded with a GaN layer using layer transfer techniques, where the silicon layer includes a transistor and the GaN layer includes a conductive layer that serves as a back gate structure for the transistor, where the transistor contacts penetrate the bonding oxide, in accordance with various embodiments. FIG. 8 may be similar to FIG. 1G, where the first layer 806 does not include a metallization layer, such as metallization layer 740 of FIG. 7.

FIG. 8 shows a first layer 806 that includes a GaN layer 802, with a first AlGaN layer 804a and a second AlGaN layer 804b on the GaN layer 802. In embodiments, a dielectric 811 may electrically isolate the first AlGaN layer 804a from the second AlGaN layer 804b. In embodiments, a first 2DEG layer 808a may form in the GaN layer 802 underneath the first AlGaN layer 804a, and a second 2DEG layer 808b may form in the second GaN layer 804b underneath the second AlGaN layer 804b.

A second layer 812, which may be silicon-based, and may be on the first layer 806 with a bonding oxide layer 820 separating the second layer 812 and the first layer 806. The second layer 812 may include a transistor 821 that may include a portion of silicon 814a that may serve as a body of the transistor 821, with a source contact 822, a drain contact 824, and a gate 826 on a side of the portion of silicon 814a. Metal vias 838, which may extend through a dielectric 813, may electrically couple, respectively, with the source contact 822, the drain contact 824, and the gate 826. In embodiments, metal vias 837 may electrically couple, respectively, with the source contact 842, the drain contact 844, and the gate 846. In embodiments, the transistor 821 may be any semiconductor structure.

In embodiments, and electrical contact 850 may extend through the second layer 812, and through the bonding oxide layer 820 to directly electrically couple with the first AlGaN layer 804a. In embodiments, a metal via 838 may electrically couple (not shown) with a top of the electrical contact 850. In embodiments, a voltage applied to the electrical contact 850 may cause the first 2DEG layer 808a within the first layer 806 to act as a field plate, thus regulating the operation of the transistor 821 in the second layer 812.

In embodiments, a source contact 842, a drain contact 844, and a gate 846 may be formed through the second layer 812, and through the bonding oxide layer 820 to directly electrically and physically couple with the second AlGaN layer 804b. In embodiments, the source contact 842, drain contact 844, and gate 846 may be formed, for example using an etching process, after the first layer 806 and the second layer 812 are layer transferred onto each other using the bonding oxide layer 820. As a result, a transistor 831 may be formed, which uses the second AlGaN layer 804b and a portion of the GaN layer 802 as a transistor body.

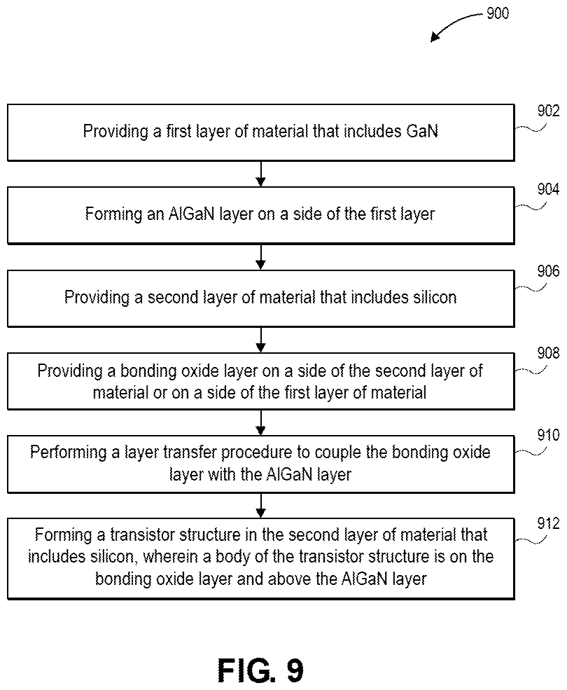

FIG. 9 illustrates an example process for manufacturing a voltage contrast structure, in accordance with various embodiments. In embodiments, the process 900 may be performed using the techniques, processes, apparatus, and/or systems described herein, and in particular with respect to FIGS. 1A-8.

At block 902, the process may include providing a first layer of material that includes GaN.

At block 904, the process may further include forming an AlGaN layer on a side of the first layer.

At block 906, the process may further include providing a second layer of material that includes silicon.

At block 908, the process may further include providing a bonding oxide layer on a side of the second layer of material or on a side of the first layer of material.

At block 910, the process may further include performing a layer transfer procedure to couple the bonding oxide layer with the AlGaN layer.

At block 912, the process may further include forming a transistor structure in the second layer of material that includes silicon, wherein a body of the transistor structure is on the bonding oxide layer and above the AlGaN layer.

Implementations of embodiments of the invention may be formed or carried out on a substrate, such as a semiconductor substrate. In one implementation, the semiconductor substrate may be a crystalline substrate formed using a bulk silicon or a silicon-on-insulator substructure. In other implementations, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V or group IV materials. Although a few examples of materials from which the substrate may be formed are described here, any material that may serve as a foundation upon which a semiconductor device may be built falls within the spirit and scope of the present invention.

A plurality of transistors, such as metal-oxide-semiconductor field-effect transistors (MOSFET or simply MOS transistors), may be fabricated on the substrate. In various implementations of the invention, the MOS transistors may be planar transistors, nonplanar transistors, or a combination of both. Nonplanar transistors include FinFET transistors such as double-gate transistors and tri-gate transistors, and wrap-around or all-around gate transistors such as nanoribbon and nanowire transistors. Although the implementations described herein may illustrate only planar transistors, it should be noted that the invention may also be carried out using nonplanar transistors.

Each MOS transistor includes a gate stack formed of at least two layers, a gate dielectric layer and a gate electrode layer. The gate dielectric layer may include one layer or a stack of layers. The one or more layers may include silicon oxide, silicon dioxide (SiO₂) and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The gate electrode layer is formed on the gate dielectric layer and may consist of at least one P-type workfunction metal or N-type workfunction metal, depending on whether the transistor is to be a PMOS or an NMOS transistor. In some implementations, the gate electrode layer may consist of a stack of two or more metal layers, where one or more metal layers are workfunction metal layers and at least one metal layer is a fill metal layer.

For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a workfunction that is between about 4.9 eV and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, and aluminum carbide. An N-type metal layer will enable the formation of an NMOS gate electrode with a workfunction that is between about 3.9 eV and about 4.2 eV.

In some implementations, the gate electrode may consist of a “U”-shaped structure that includes a bottom portion substantially parallel to the surface of the substrate and two sidewall portions that are substantially perpendicular to the top surface of the substrate. In another implementation, at least one of the metal layers that form the gate electrode may simply be a planar layer that is substantially parallel to the top surface of the substrate and does not include sidewall portions substantially perpendicular to the top surface of the substrate. In further implementations of the invention, the gate electrode may consist of a combination of U-shaped structures and planar, non-U-shaped structures. For example, the gate electrode may consist of one or more U-shaped metal layers formed atop one or more planar, non-U-shaped layers.

In some implementations of the invention, a pair of sidewall spacers may be formed on opposing sides of the gate stack that bracket the gate stack. The sidewall spacers may be formed from a material such as silicon nitride, silicon oxide, silicon carbide, silicon nitride doped with carbon, and silicon oxynitride. Processes for forming sidewall spacers are well known in the art and generally include deposition and etching process steps. In an alternate implementation, a plurality of spacer pairs may be used, for instance, two pairs, three pairs, or four pairs of sidewall spacers may be formed on opposing sides of the gate stack.

As is well known in the art, source and drain regions are formed within the substrate adjacent to the gate stack of each MOS transistor. The source and drain regions are generally formed using either an implantation/diffusion process or an etching/deposition process. In the former process, dopants such as boron, aluminum, antimony, phosphorous, or arsenic may be ion-implanted into the substrate to form the source and drain regions. An annealing process that activates the dopants and causes them to diffuse further into the substrate typically follows the ion implantation process. In the latter process, the substrate may first be etched to form recesses at the locations of the source and drain regions. An epitaxial deposition process may then be carried out to fill the recesses with material that is used to fabricate the source and drain regions. In some implementations, the source and drain regions may be fabricated using a silicon alloy such as silicon germanium or silicon carbide. In some implementations the epitaxially deposited silicon alloy may be doped in situ with dopants such as boron, arsenic, or phosphorous. In further embodiments, the source and drain regions may be formed using one or more alternate semiconductor materials such as germanium or a group III-V material or alloy. And in further embodiments, one or more layers of metal and/or metal alloys may be used to form the source and drain regions.

One or more interlayer dielectrics (ILD) are deposited over the MOS transistors. The ILD layers may be formed using dielectric materials known for their applicability in integrated circuit structures, such as low-k dielectric materials. Examples of dielectric materials that may be used include, but are not limited to, silicon dioxide (SiO₂), carbon doped oxide (CDO), silicon nitride, organic polymers such as perfluorocyclobutane or polytetrafluoroethylene, fluorosilicate glass (FSG), and organosilicates such as silsesquioxane, siloxane, or organosilicate glass. The ILD layers may include pores or air gaps to further reduce their dielectric constant.

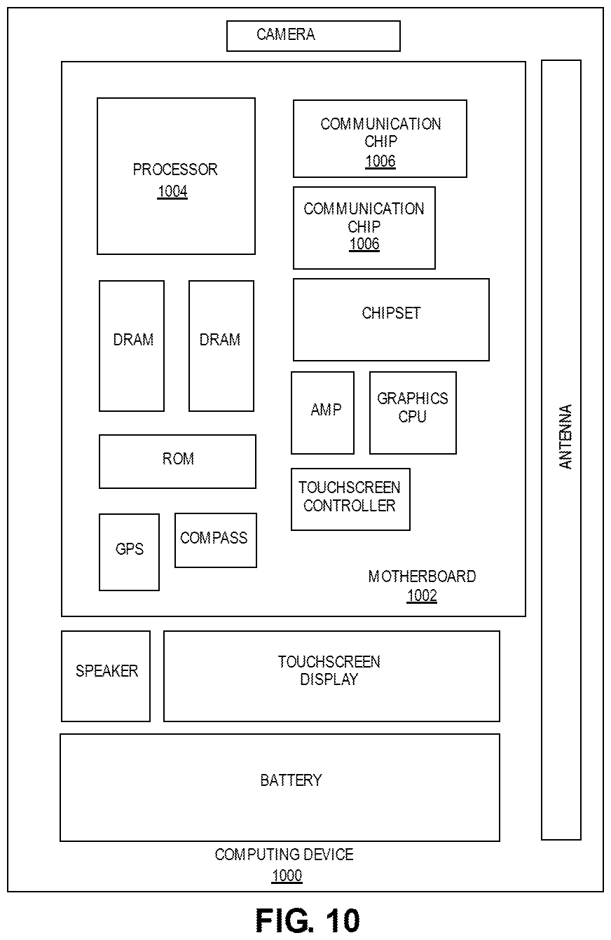

FIG. 10 illustrates a computing device 1000 in accordance with one implementation of the invention. The computing device 1000 houses a board 1002. The board 1002 may include a number of components, including but not limited to a processor 1004 and at least one communication chip 1006. The processor 1004 is physically and electrically coupled to the board 1002. In some implementations the at least one communication chip 1006 is also physically and electrically coupled to the board 1002. In further implementations, the communication chip 1006 is part of the processor 1004.

Depending on its applications, computing device 1000 may include other components that may or may not be physically and electrically coupled to the board 1002. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 1006 enables wireless communications for the transfer of data to and from the computing device 1000. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1006 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 1000 may include a plurality of communication chips 1006. For instance, a first communication chip 1006 may be dedicated to shorter range wireless communications such as Wi-Fi and Bluetooth and a second communication chip 1006 may be dedicated to longer range wireless communications such as GPS, EDGE, GPRS, CDMA, WiMAX, LTE, Ev-DO, and others.

The processor 1004 of the computing device 1000 includes an integrated circuit die packaged within the processor 1004. In some implementations of the invention, the integrated circuit die of the processor includes one or more devices, such as MOS-FET transistors built in accordance with implementations of the invention. The term “processor” may refer to any device or portion of a device that processes electronic data from registers and/or memory to transform that electronic data into other electronic data that may be stored in registers and/or memory.

The communication chip 1006 also includes an integrated circuit die packaged within the communication chip 1006. In accordance with another implementation of the invention, the integrated circuit die of the communication chip includes one or more devices, such as MOS-FET transistors built in accordance with implementations of the invention.

In further implementations, another component housed within the computing device 1000 may contain an integrated circuit die that includes one or more devices, such as MOS-FET transistors built in accordance with implementations of the invention.

In various implementations, the computing device 1000 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 1000 may be any other electronic device that processes data.

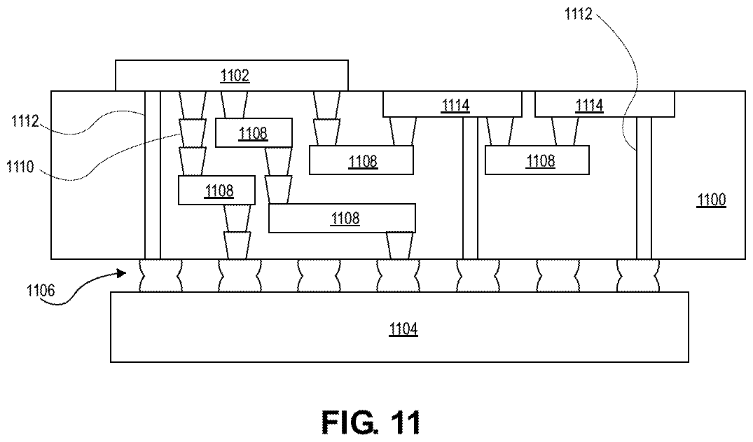

FIG. 11 illustrates an interposer 1100 that includes one or more embodiments of the invention. The interposer 1100 is an intervening substrate used to bridge a first substrate 1102 to a second substrate 1104. The first substrate 1102 may be, for instance, an integrated circuit die. The second substrate 1104 may be, for instance, a memory module, a computer motherboard, or another integrated circuit die. Generally, the purpose of an interposer 1100 is to spread a connection to a wider pitch or to reroute a connection to a different connection. For example, an interposer 1100 may couple an integrated circuit die to a ball grid array (BGA) 1106 that can subsequently be coupled to the second substrate 1104. In some embodiments, the first and second substrates 1102/1104 are attached to opposing sides of the interposer 1100. In other embodiments, the first and second substrates 1102/1104 are attached to the same side of the interposer 1100. And in further embodiments, three or more substrates are interconnected by way of the interposer 1100.

The interposer 1100 may be formed of an epoxy resin, a fiberglass-reinforced epoxy resin, a ceramic material, or a polymer material such as polyimide. In further implementations, the interposer 1100 may be formed of alternate rigid or flexible materials that may include the same materials described above for use in a semiconductor substrate, such as silicon, germanium, and other group III-V and group IV materials.

The interposer 1100 may include metal interconnects 1108 and vias 1110, including but not limited to through-silicon vias (TSVs) 1112. The interposer 1100 may further include embedded devices 1114, including both passive and active devices. Such devices include, but are not limited to, capacitors, decoupling capacitors, resistors, inductors, fuses, diodes, transformers, sensors, and electrostatic discharge (ESD) devices. More complex devices such as radio-frequency (RF) devices, power amplifiers, power management devices, antennas, arrays, sensors, and MEMS devices may also be formed on the interposer 1100. In accordance with embodiments of the invention, apparatuses or processes disclosed herein may be used in the fabrication of interposer 1100.

Although certain embodiments have been illustrated and described herein for purposes of description, a wide variety of alternate and/or equivalent embodiments or implementations calculated to achieve the same purposes may be substituted for the embodiments shown and described without departing from the scope of the present disclosure. This application is intended to cover any adaptations or variations of the embodiments discussed herein. Therefore, it is manifestly intended that embodiments described herein be limited only by the claims.

Where the disclosure recites “a” or “a first” element or the equivalent thereof, such disclosure includes one or more such elements, neither requiring nor excluding two or more such elements. Further, ordinal indicators (e.g., first, second or third) for identified elements are used to distinguish between the elements, and do not indicate or imply a required or limited number of such elements, nor do they indicate a particular position or order of such elements unless otherwise specifically stated.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or to limit embodiments to the precise forms disclosed. While specific embodiments are described herein for illustrative purposes, various equivalent modifications are possible within the scope of the embodiments, as those skilled in the relevant art will recognize.

These modifications may be made to the embodiments in light of the above detailed description. The terms used in the following claims should not be construed to limit the embodiments to the specific implementations disclosed in the specification and the claims. Rather, the scope of the invention is to be determined entirely by the following claims, which are to be construed in accordance with established doctrines of claim interpretation.

The following paragraphs describe examples of various embodiments.

### EXAMPLES

Example 1 is a device comprising: a first layer, wherein the first layer includes a conductive layer and a bonding oxide layer on top of the conductive layer; a second layer, wherein the second layer is on top of the first layer, and wherein the second layer includes a semiconductor structure on top of the bonding oxide layer; and wherein a portion of the conductive layer is proximate to the semiconductor structure.

Example 2 includes the device of example 1, wherein the conductive layer and the semiconductor structure are separated by a distance perpendicular to the bonding oxide layer that is less than 100 nm.

Example 3 includes the device of examples 1 or 2, wherein the first layer includes a selected one or more of: GaN, Al, AlGaN, SiC, SiGe, a group III-V material, or Si.

Example 4 includes the device of examples 1, 2, or 3, wherein the conductive layer is a selected one or more of: a metal layer or a conductive semiconductor region.

Example 5 includes the device of example 4, wherein the conductive semiconductor region is a doped region of SiC, group III-V, Si, GaN, or AlGaN, or a 2D electron gas induced by a junction of AlGaN and GaN.

Example 6 includes the device of examples 1, 2, 3, 4, or 5, wherein the conductive layer is adjacent to the bonding oxide layer.

Example 7 includes the device of examples 1, 2, 3, 4, 5, or 6, wherein the portion of the device is adjacent to the bonding oxide layer.

Example 8 includes the device of examples 1, 2, 3, 4, 5, 6, or 7, wherein the device is a transistor.

Example 9 includes the device of examples 1, 2, 3, 4, 5, 6, 7, or 8, wherein the semiconductor structure is a portion of a transistor.

Example 10 includes the device of example 9, wherein the portion of the conductive layer is a selected one or more of: a back gate structure or a field plate.

Example 11 includes the device of examples 1, 2, 3, 4, 5, 6, 7, 8, 9, or 10, further comprising an electrical connection extending from the second layer through the bonding oxide layer and into the first layer, wherein the electrical connection is electrically coupled with the portion of the conductive layer.

Example 12 includes the device of examples 1, 2, 3, 4, 5, 6, 7, 8, 9, 10, or 11, wherein the portion of the conductive layer is a first portion of the conductive layer; and further comprising a second portion of the conductive layer, wherein the first portion of the conductive layer and the second portion of the conductive layer are electrically isolated from each other.

Example 13 includes the device of examples 1, 2, 3, 4, 5, 6, 7, 8, 9, 10, 11, or 12, wherein the second layer includes silicon, and wherein the semiconductor structure includes silicon.

Example 14 includes the device of examples 1, 2, 3, 4, 5, 6, 7, 8, 9, 10, 11, 12, or 13, wherein during operation of the device the portion of the conductive layer alters an electric field generated by the semiconductor structure.

Example 15 is a transistor comprising: a first layer, wherein the first layer includes an electrically conductive layer that includes gallium (Ga) and nitrogen (N) and a bonding oxide layer on top of the conductive layer; a second layer on the first layer, wherein the second layer includes a body, wherein the body includes silicon and is on top of the bonding oxide layer; and wherein the body is proximate to a portion of the conductive layer, wherein the conductive layer forms a back gate structure for the body.

Example 16 includes the transistor of example 15, wherein the conductive layer and the body are separated by a distance perpendicular to the bonding oxide layer that is less than 100 nm.

Example 17 includes the transistor of examples 15 or 16, wherein the body is adjacent to the bonding oxide layer or the portion of the conductive layer is adjacent to the bonding oxide layer.

Example 18 includes the transistor of examples 15, 16, or 17, wherein a source contact extends through the bonding oxide layer and is electrically coupled with the portion of the conductive layer.

Example 19 includes the transistor of examples 15, 16, 17, or 18, further comprising a gate between the source contact and the drain contact, wherein the gate extends around the body and through the bonding oxide layer, and wherein the gate is electrically coupled with the portion of the conductive layer.

Example 20 includes the transistor of examples 15, 16, 17, 18, or 19, wherein the conductive layer is a 2D electron gas (2DEG) channel.

Example 21 includes the transistor of example 20, wherein the first layer further includes an AlGaN layer between the oxide layer and the portion of the conductive layer, wherein the portion of the conductive layer includes GaN, and wherein the 2DEG channel is proximate to the AlGaN layer.

Example 22 is a method comprising: providing a first layer of material that includes GaN; forming an AlGaN layer on a side of the first layer of material; providing a second layer of material that includes silicon; providing a bonding oxide layer on a side of the second layer of material or on a side of the first layer of material; performing a layer transfer procedure to couple the bonding oxide layer with the AlGaN layer; and forming a transistor structure in the second layer of material that includes silicon, wherein a body of the transistor structure is on the bonding oxide layer and above the AlGaN layer.

Example 23 includes the method of example 22, further comprising, after the step of forming the AlGaN layer on the side of the first layer of material, forming a metal layer on the AlGaN layer; and wherein performing a layer transfer procedure to couple the bonding oxide layer with the AlGaN layer further includes performing a layer transfer procedure to couple the bonding oxide layer to the formed metal layer on the AlGaN layer.

Example 24 includes the method of examples 22 or 23, wherein a distance perpendicular to the bonding oxide layer between the transistor structure and the AlGaN layer is less than 100 nm.

Example 25 includes the method of examples 22, 23, or 24, wherein the second layer of material has a thickness that is less than 500 nm.

Example 26 includes the device of examples 1, 2, 3, 4, 5, 6, 7, 8, 9. 10, 11, 12, 13 or 14, wherein the device is a first device, and wherein the portion of the conductive layer or wherein the portion of the first device is a portion of a second device that is different than the first device.

Example 27 includes the device of examples 1, 2, 3, 4, 5, 6, 7, 8, 9. 10, 11, 12, 13, 14 or 26, wherein the first layer is on top of the second layer.

What is claimed is:

1. A device comprising:
a first layer, wherein the first layer includes a conductive layer and a bonding oxide layer on top of the conductive layer;
a second layer, wherein the second layer is on top of the first layer, and wherein the second layer includes a semiconductor structure on top of the bonding oxide layer; and
wherein a portion of the conductive layer is proximate to the semiconductor structure.

2. The device of claim 1, wherein the conductive layer and the semiconductor structure are separated by a distance perpendicular to the bonding oxide layer that is less than 100 nm.

3. The device of claim 1, wherein the first layer includes a selected one or more of: GaN, Al, AlGaN, SiC, SiGe, a group III-V material, or Si.

4. The device of claim 1, wherein the conductive layer is a selected one or more of: a metal layer or a conductive semiconductor region.

5. The device of claim 4, wherein the conductive semiconductor region is a doped region of SiC, group III-V, Si, GaN, or AlGaN, or a 2D electron gas induced by a junction of AlGaN and GaN.

6. The device of claim 1, wherein the conductive layer is adjacent to the bonding oxide layer.

7. The device of claim 1, wherein the portion of the device is adjacent to the bonding oxide layer.

8. The device of claim 1, wherein the device is a transistor.

9. The device of claim 1, wherein the semiconductor structure is a portion of a transistor.

10. The device of claim 9, wherein the portion of the conductive layer is a selected one or more of: a back gate structure or a field plate.

11. The device of claim 1, further comprising an electrical connection extending from the second layer through the bonding oxide layer and into the first layer, wherein the electrical connection is electrically coupled with the portion of the conductive layer.

12. The device of claim 1, wherein the portion of the conductive layer is a first portion of the conductive layer; and further comprising a second portion of the conductive layer, wherein the first portion of the conductive layer and the second portion of the conductive layer are electrically isolated from each other.

13. The device of claim 1, wherein the second layer includes silicon, and wherein the semiconductor structure includes silicon.

14. The device of claim 1, wherein during operation of the device the portion of the conductive layer alters an electric field generated by the semiconductor structure.

15. A transistor comprising:
a first layer, wherein the first layer includes an electrically conductive layer that includes gallium (Ga) and nitrogen (N) and a bonding oxide layer on top of the conductive layer;
a second layer on the first layer, wherein the second layer includes a body wherein the body includes silicon and is on top of the bonding oxide layer; and
wherein the body is proximate to a portion of the conductive layer, wherein the conductive layer forms a back gate structure for the body.

16. The transistor of claim 15, wherein the conductive layer and the body are separated by a distance perpendicular to the bonding oxide layer that is less than 100 nm.

17. The transistor of claim 15, wherein the body is adjacent to the bonding oxide layer or the portion of the conductive layer is adjacent to the bonding oxide layer.

18. The transistor of claim 15, wherein a source contact extends through the bonding oxide layer and is electrically coupled with the portion of the conductive layer.

19. The transistor of claim 15, further comprising a gate between the source contact and the drain contact, wherein the gate extends around the body and through the bonding oxide layer, and wherein the gate is electrically coupled with the portion of the conductive layer.

20. The transistor of claim 15, wherein the conductive layer is a 2D electron gas (2DEG) channel.

21. The transistor of claim 20, wherein the first layer further includes an AlGaN layer between the oxide layer and the portion of the conductive layer, wherein the portion of the conductive layer includes GaN, and wherein the 2DEG channel is proximate to the AlGaN layer.

22. A method comprising:
providing a first layer of material that includes GaN;
forming an AlGaN layer on a side of the first layer of material;
providing a second layer of material that includes silicon;
providing a bonding oxide layer on a side of the second layer of material or on a side of the first layer of material;
performing a layer transfer procedure to couple the bonding oxide layer with the AlGaN layer; and
forming a transistor structure in the second layer of material that includes silicon, wherein a body of the transistor structure is on the bonding oxide layer and above the AlGaN layer.

23. The method of claim 22, further comprising, after the step of forming the AlGaN layer on the side of the first layer of material, forming a metal layer on the AlGaN layer; and wherein performing a layer transfer procedure to couple the bonding oxide layer with the AlGaN layer further includes performing a layer transfer procedure to couple the bonding oxide layer to the formed metal layer on the AlGaN layer.

24. The method of claim 22, wherein a distance perpendicular to the bonding oxide layer between the transistor structure and the AlGaN layer is less than 100 nm.

25. The method of claim 22, wherein the second layer of material has a thickness that is less than 500 nm.
